(19) United States
(12) Patent Application Publication
(10) Pub. No.: US 2009/0039354 A1
(43) Pub. Date: Feb. 12, 2009

(54) TFT ARRAY SUBSTRATE AND MANUFACTURING METHOD THEREOF

(76) Inventors: Zhangtao WANG, Beijing (CN); Xiang LIU, Beijing (CN); Haijun QIU, Beijing (CN)

Correspondence Address: LADAS & PARRY LLP, 224 SOUTH MICHIGAN AVENUE, SUITE 1600, CHICAGO, IL, 60604, US

(21) Appl. No.: 12/125,100

(22) Filed: May 22, 2008

(30) Foreign Application Priority Data
Aug. 10, 2007 (CN) 200710120167.1

(51) Int. Cl. H01L 33/00; H01L 21/336

(52) U.S. Cl. 257/72; 438/34; 257/E33.053; 257/E21.411

(57) ABSTRACT

Provided are a thin film transistor (TFT) array substrate and the method manufacturing thereof. The TFT array substrate comprising: a substrate, and a gate line and a data line formed on the substrate, the gate line and the data line being separated by a gate insulating layer therebetween and intersecting to define a pixel unit, the pixel unit at least including a TFT device and a pixel electrode. The data line and a source electrode of the thin film transistor device are formed as an integral structure, and an active layer is formed below both the data line and the source electrode of the thin film transistor device.

### BACKGROUND OF THE INVENTION

The present invention relates to a thin film transistor (TFT) array substrate and a manufacturing method thereof.

In order to reduce price of thin film transistor liquid crystal displays (TFT LCDs) and improve yield, the manufacturing method for a TFT array substrate of a TFT LCD has been simplified and has been developed from the initial seven- or six-photolithograph process to the current normally used five-photolithograph process. Recently, the four-photolithograph process based on slit mask technique has been introduced in the TFT LCD manufacturing field, which uses a slit mask to substitute for the masks for the second photolithograph (the active layer photolithograph) and the third photolithograph (the source-drain conductor layer photolithograph) in the five-photolithograph process. The particulars of this four-photolithograph process are described as follows.

First, a gate electrode is formed on a substrate from a gate conductor layer in the first photolithograph. Next, a gate insulating layer, an active layer, an ohmic contact layer, and a source-drain conductor layer are sequentially deposited on the substrate with the gate electrode. Then, a date line, an active island, a source electrode, a drain electrode, and a TFT channel are formed in the second photolithograph with wet etching of the source-drain conductor layer and a multi-step etching of the stacked layers (active layer etching->ashing of a photoresist pattern->etching of the source-drain conductor layer in a channel region->etching of the ohmic contact layer) after a process with a slit mask. Subsequently, a passivation layer is deposited on the substrate, and via holes are formed in the passive layer in the third photolithograph. Finally, a layer of transparent conductive layer is deposited and patterned to form a pixel electrode in the fourth photolithograph.

Compared with the conventional five-photolithograph process, the main feature of the four-photolithograph process is that the active layer pattern and the source-drain conductor pattern are formed in the same slit mask process, so that the production cycle for manufacturing the TFT array substrate can be shorten, and the production cost can be reduced. However, due to application of the slit mask process, it is necessary for the slit mask to have a high fabricating precision, and at the same time, the difficulty for the development process and the cost control may be dramatically increased, which in turn gives rise to more difficulty for improving the yield.

The mechanism of slit mask is to control the transmission of a slit mask by optical diffraction of slits so that the thickness of the photoresist can be selectively controlled, and in turn the thickness of the photoresist has obvious effect on the channel length of a TFT device to be formed, that is to say, the electrical characteristics of the TFT device. However, since the fabricating precision of the slit mask is limited, the uniformity of the electrical characteristic across the entire substrate may be reduced, which disadvantageously affects the display quality of the produced LCDs and even causes bad pixels, and in addition, the yield is dramatically decreased.

The multiple-step etching process mentioned above is one of the essential components of the photolithograph process with a slit mask and is performed to form the active layer pattern and the source-drain conductor layer pattern as well as the TFT channel in the second photolithograph, therefore the process is complicated. The process comprises etching of the active layer, ashing of the photoresist pattern at the channel region, etching of the source-drain conductor layer at the channel region, and etching of the ohmic contact layer, and all these etching processes are performed in the same equipment chamber, so that it is difficult to control the process and the requirement for the equipment is also high, bringing about a big challenge for obtaining a high yield.

### SUMMARY OF THE INVENTION

An embodiment of the invention provides a TFT array substrate, comprising a substrate, a gate line and a data line formed on the substrate, the gate line and the data line being separated by a gate insulating layer therebetween and intersecting each other to define a pixel unit, and the pixel unit at least including a TFT device and a pixel electrode, wherein a gate electrode of the TFT device is connected with the gate line, and a drain electrode of the TFT device is connected with the pixel electrode, and wherein the data line and a source electrode of the thin film transistor device are formed as an integral structure, and an active layer is formed below both the data line and the source and drain electrodes of the TFT device.

Another embodiment of the invention provides a method of manufacturing TFT array substrate, comprising:

step 1, depositing a gate conductor layer on a substrate and patterning the gate conductor layer to form a gate electrode and a gate line;

step 2, on the substrate after step 1, sequentially depositing a gate insulating layer, an active layer, a source-drain conductor layer and then forming a data line and a source-drain electrode pattern, wherein the active layer is left below the data line and the source-drain electrode pattern after the patterning;

step 3, on the substrate after step 2, depositing a passivation layer and patterning the passivation layer to form via holes so as to expose the source-drain conductor layer at a drain electrode and at a channel region of a TFT device, respectively; and

step 4, on the substrate after step 3, depositing a transparent conductive layer and patterning the transparent conductive layer into a pixel electrode, and then etching a portion of the source-drain conductor layer at the channel region and the active layer at the channel region so as to form the channel of the TFT device, wherein the pixel electrode is connected with the drain electrode through the via hole formed at the drain electrode.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the following detailed description.

### BRIEF DESCRIPTION OF THE DRAWINGS

The present invention will become more fully understood from the detailed description given hereinafter and the accompanying drawings which are given by way of illustration only, and thus are not limitative of the present invention and wherein:

FIG. 1 is a plan schematic view of a pixel unit in the TFT array substrate according to an embodiment of the invention;

FIG. 2 is a cross-sectional view taken along line I-I in FIG. 1;

FIG. 3 is a plan view after a first photolithograph is completed according to the embodiment of the invention;

FIG. 4 is a cross-sectional view taken along line II-II in FIG. 3;

FIG. 5 is a plan schematic view after a second photolithograph is completed according to the embodiment of the invention;

FIG. 6 is a cross-sectional view taken along line III-III in FIG. 5;

FIG. 7 is a plan schematic view after the third photolithograph is completed according to the embodiment of the invention;

FIG. 8 is a cross-sectional view taken along line IV-IV in FIG. 7;

FIG. 9 is a plan view after the fourth photolithograph is completed according to the embodiment of the invention; and

FIG. 10 is a cross-sectional taken along line V-V in FIG. 9.

### DETAILED DESCRIPTION OF THE PREFERRED EMBODIMENTS

Exemplary embodiments of the present invention will be described hereinafter with reference to the accompanying drawings. However, the present can be realized in different ways and should not be limited to the embodiments set forth hereinafter. It should be understood by those skilled in the art that in this description when a layer or a element is referred to as being “on” or “connected to” another layer or element, this layer or element can be directly on or directly connected to the other layer or element, or an intervening layer may also be present therebetween.

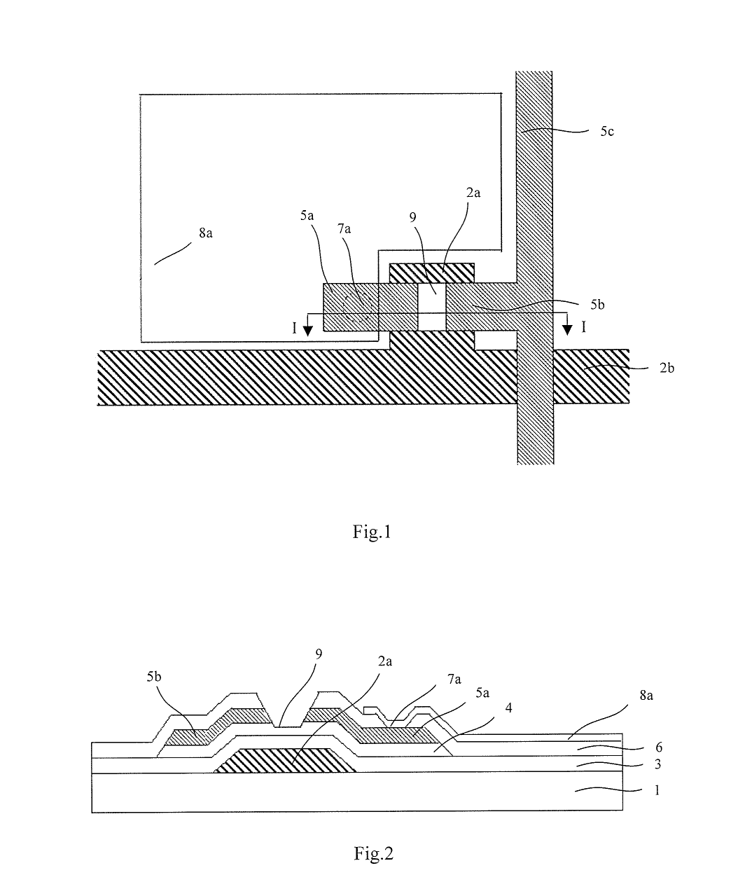

FIG. 1 shows a plan schematic view of one pixel unit in a TFT array substrate of an embodiment of the invention; and FIG. 2 is a cross-sectional view taken along line I-I at a part of the thin film transistor in FIG. 1.

As shown in FIGS. 1 and 2, the TFT array substrate of the embodiment comprises a substrate 1 and a gate line 2b and a data line 5c which are formed on the substrate 1, and the gate line 2b and the data line 5c intersect each other to define a pixel unit. Each pixel unit at least comprises a thin film transistor device as a switching device and a pixel electrode 8a, as shown in FIG. 1. A gate conductor layer (including a gate electrode 2a and the gate line 2b), a gate insulating layer 3, an active layer 4, a drain electrode 5a and a source electrode 5b of the thin film transistor device are formed on the substrate 1 in this order. A passivation layer 6 is formed on the gate insulating layer 3 and the source and drain electrodes; a pixel electrode 8a covers the passive layer 6 in the pixel unit and is connected with the drain electrode 5a though a contact hole 7a in the passivation layer 6, as shown in FIG. 2. The active layer 4 may comprise a semiconductor layer and an ohmic contact layer on the semiconductor layer. In the embodiment of the invention, the data line 5c and the source electrode 5b are formed integrally, and the active layer 4 and the gate insulating layer 3 are formed below the data line 5c, the source electrode 5b and the drain electrode 5a.

In the embodiment, a four-photolithograph process is used to form the above array substrate, and the process may comprise a first photolithograph for forming the pattern of the gate electrode and the gate line; a second photolithograph for forming the pattern for the active layers data line and the source and drain electrodes; a third photolithograph for forming the pattern of the passivation layer; and a fourth photolithograph for forming the pattern of the pixel electrode and the TFT channel.

FIGS. 1-10 show a process for manufacturing a TFT array substrate by a four-photolithograph process according to an embodiment of the invention.

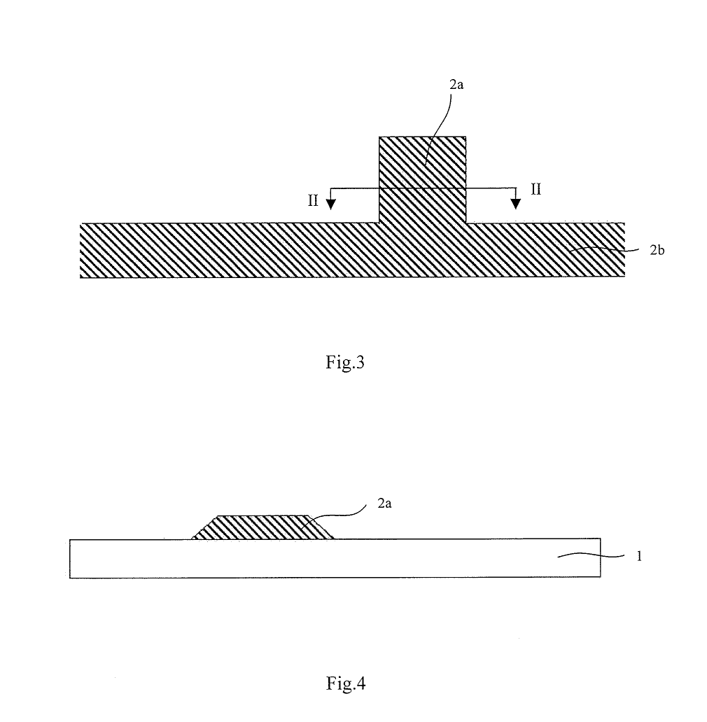

First, on a transparent substrate 1, such as a quartz or a transparent glass substrate, a gate conductor layer with a thickness of about 500˜4000 Å is deposited by sputtering or thennal evaporation. The gate conductor layer may be a single layer film formed of a material selected from the group consisting of Cr, W, Ti, Ta, Mo, Al, Cu and the alloy thereof, or a multilayer film formed of stacked layers of a material selected from the group consisting of Cr, W, Ti, Ta, Mo, Al, Cu and the alloy thereof. A gate electrode 2a and a gate line 2b are formed by the first photolithograph and etching process, and the plan view and the cross-sectional view taken along line II-II at the gate electrode are shown in FIGS. 3 and 4, respectively.

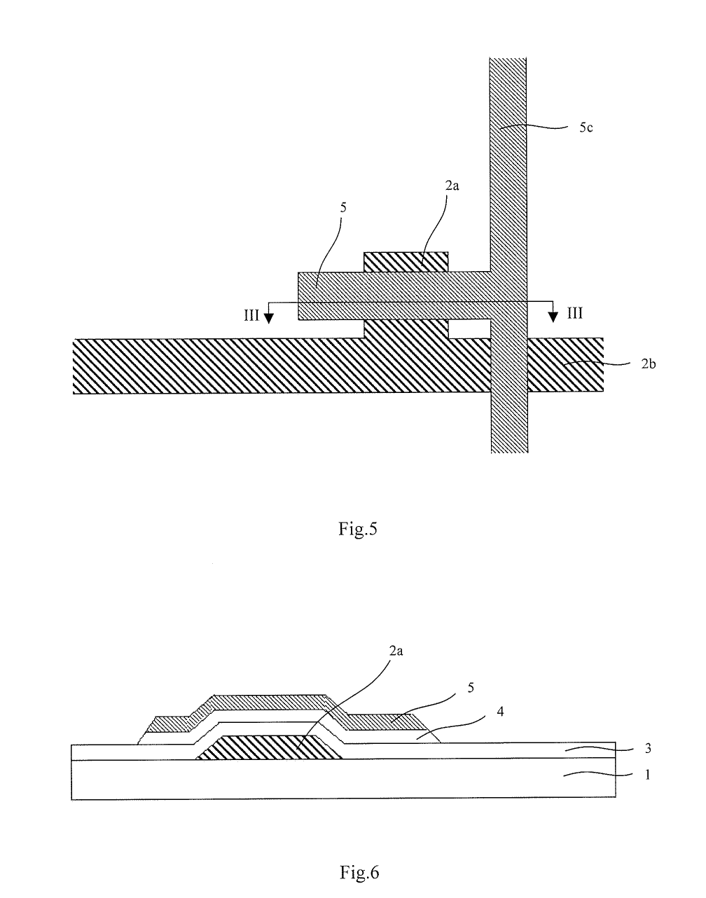

Next, a gate insulating layer 3 with a thickness of about 1000-4000 Å and an active layer 4 (for example, including a semiconductor layer and an ohmic contact layer) with a thickness of about 1000-3500 Å are sequentially deposited, for example, by plasma enhanced chemical vapor deposition (PECVD). The gate insulating layer 3 may be oxide, nitride or oxynitride, and the corresponding reaction gases comprise SiH₄, NH₃, and N₂, or SiH₂Cl₂, NH₃, and N₂. The reaction gases corresponding to the active layer 4 may be SiH₄ and H₂, or SiH₂Cl₂ and H₂ so as to obtain a semiconductor layer of amorphous silicon, for example. Further, a doped ohmic contact layer of n+ amorphous silicon is formed on the semiconductor layer, and the reaction gases may be PH₃, SiH₄ and H₂, thus obtaining the active layer 4 of stacked layers of the semiconductor layer and the ohmic contact layer. Then, a source-drain conductor layer 5 with a thickness of about 500˜2500 Å is deposited on the active layer 4 by sputtering or thermal evaporation. The source-drain conductor layer 5 may be also a single layer film formed of a material selected from the group consisting of Cr, W, Ti, Ta, Mo, Al, Cu and the alloy thereof, or a multilayer film formed of stacked layers of a material selected from the group consisting of Cr, W, Ti, Ta, Mo, Al, Cu and the alloy thereof. After the source-drain conductor layer 5 is deposited, the patterns for the active layer, the source and drain electrodes and the data line 5c are formed by the second photolithograph and etching process, and the plan schematic view and the cross-sectional view taken along line III-III at the gate electrode are shown in FIGS. 5 and 6, respectively.

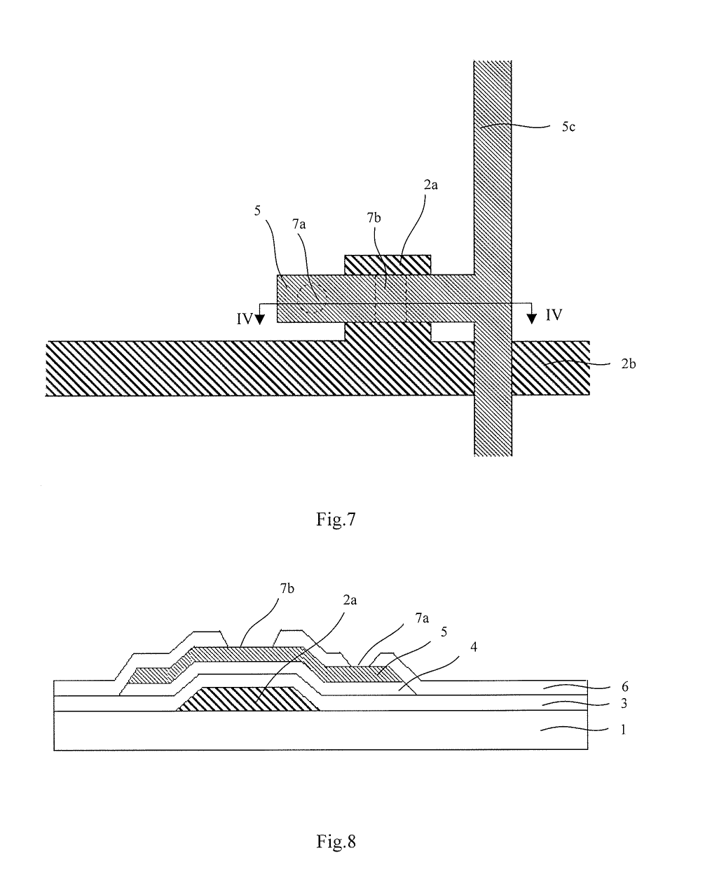

Subsequently, a passivation layer 6 with a thickness of about 700˜2000 Å is deposited, for example, by PECVD. The passivation layer 6 may be formed of a material selected from the group of oxide, nitride, and oxynitride, and the corresponding reaction gases may be SiH₄, NH₃, and N₂, or SiH₂Cl₂, NH₃, and N₂. Then, a contact hole 7a and another via hole at the channel region 7b are formed by the third photolithograph and etching process, and the etching gases may be SF₆/O₂, Cl₂/O₂, or HCl/O₂. The plan schematic view and the cross-sectional view taken along line IV-IV at the gate electrode after etching are shown in FIGS. 7 and 8, respectively.

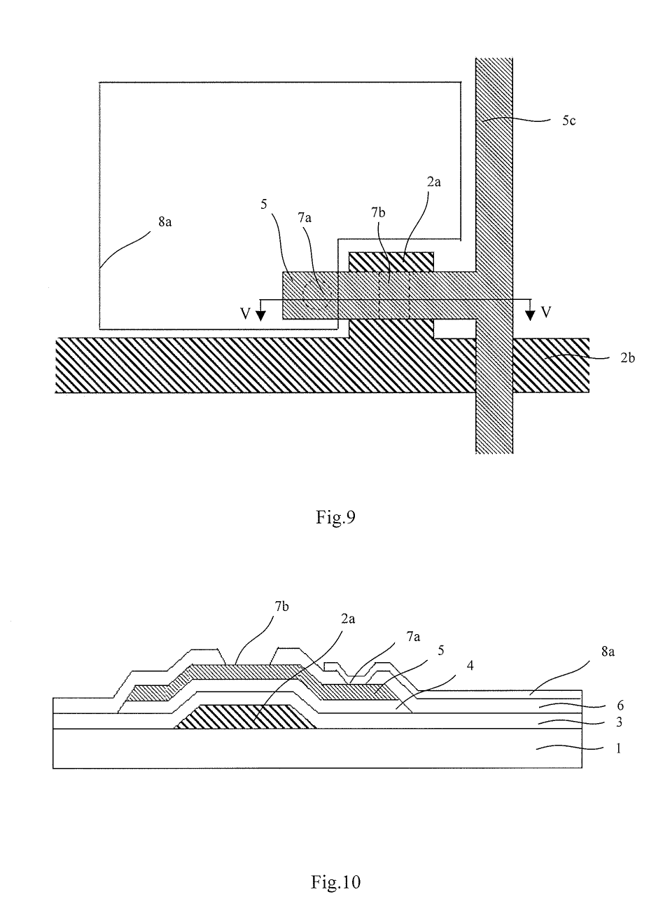

After that, a pixel electrode layer 8 with a thickness of about 300˜600 Å is deposited, for example, by sputtering or thermal evaporation, and the pixel electrode layer 8 may be formed of a transparent conductive material, such as indium tin oxide (ITO), indium zinc oxide (IZO), tin oxide and the like. Finally, a pixel electrode 8a is formed by the fourth photolithograph and the etching process, and the plan schematic view and the cross-sectional view at the gate electrode taken along line V-V are shown in FIGS. 9 and 10, respectively.

After the pixel electrode 8a is formed, the photoresist on the pixel electrode 8a which is used in the fourth photolithograph is not lifted off. The source-drain conductor layer 5 and a part of the active layer 4 in the via hole at the channel region 7b are etched to form the source and drain electrodes 5b, 5a and cut off the ohmic contact layer, so that the channel 9 of the thin film transistor device is formed and the fabrication of the array structure is completed, and the plan schematic view and the cross-sectional view taken along line I-I at the gate electrode are shown in FIGS. 1 and 2, respectively.

Compared with the conventional four-photolithograph process for manufacturing a TFT array substrate, the implementation of the invention has one or more of the following characteristics: first, only the pattern for the active layer and the source-drain conductor layer are formed in the second photolithograph, but the source-drain conductor layer is not cut off to form the source and drain electrodes, and therefore, the application of a slit mask process can be avoided; and second, in the fourth photolithograph, not only the pixel electrode pattern is formed, but also the TFT channel is formed.

Compared with the conventional techniques, the embodiment of the invention has one or more of the following obvious advantages at least:

First, since a slit mask is not used, the cost for manufacturing the slit mask can be reduced and the strict requirement on the precision of the mask can be eliminated.

Second, since a slit mask is not used, the difficulty of photolithograph process and the etching process can be greatly decreased, which can shorten the development period dramatically.

Third, since a slit mask is not used, bad pixels due to usage of the slit mask can be reduced dramatically, which is helpful to increase yield.

The invention being thus described, it will be obvious that the same may be varied in many ways. Such variations are not to be regarded as a departure from the spirit and scope of the invention, and all such modifications as would be obvious to those skilled in the art are intended to be comprised within the scope of the following claims.

What is claimed is:

1. A thin film transistor (TFT) array substrate, comprising:
a substrate,
a gate line and a data line formed on the substrate, the gate line and the data line being separated by a gate insulating layer therebetween and intersecting each other to define a pixel unit, and the pixel unit at least including a TFT device and a pixel electrode,
wherein a gate electrode of the TFT device is connected with the gate line, and a drain electrode of the TFT device is connected with the pixel electrode, and
wherein the data line and a source electrode of the thin film transistor device are formed as an integral structure, and an active layer is formed below both the data line and the source and drain electrodes of the TFT device.

2. The TFT array substrate of claim 1, wherein the gate line is a single layer film formed of a material selected from the group consisting of Cr, W, Ti, Ta, Mo, Al, Cu, and the alloy thereof.

3. The TFT array substrate of claim 1, wherein the gate line is a multilayer film formed of stacked layers of a material selected from the group consisting of Cr, W, Ti, Ta, Mo, Al, Cu and the alloy thereof.

4. The TFT array substrate of claim 1, wherein the source and drain electrodes and the data line are a single layer film formed of one selected from the group consisting of Cr, W, Ti, Ta, Mo, Al, Cu, and the alloy thereof.

5. The TFT array substrate of claim 1, wherein the source and drain electrodes and the data line are a multilayer film formed of stacked layers of anyone selected from the group consisting of Cr, W, Ti, Ta, Mo, Al, Cu, and the alloy thereof.

6. The TFT array substrate of claim 1, wherein the active layer comprises a semiconductor layer and an ohmic contact layer on the semiconductor layer, and the ohmic contact layer contacts with the source and drain electrodes and the data line.

7. The TFT array substrate of claim 1, wherein the material of the gate insulating layer is formed of one selected from the group consisting of oxide, nitride, and oxynitride.

8. A method of manufacturing a thin film transistor (TFT) array substrate, comprising the steps of:
step 1, depositing a gate conductor layer on a substrate and patterning the gate conductor layer to form a gate electrode and a gate line;
step 2, on the substrate after step 1, sequentially depositing a gate insulating layer, an active layer, a source-drain conductor layer and then forming a data line and a source-drain electrode pattern, wherein the active layer is left below the data line and the source-drain electrode pattern after the patterning;
step 3, on the substrate after step 2, depositing a passivation layer and patterning the passivation layer to form via holes so as to expose the source-drain conductor layer at a drain electrode and at a channel region of a TFT device, respectively; and
step 4, on the substrate after step 3, depositing a transparent conductive layer and patterning the transparent conductive layer into a pixel electrode, and then etching a portion of the source-drain conductor layer at the channel region and the active layer at the channel region so as to form the channel of the TFT device, wherein the pixel electrode is connected with the drain electrode through the via hole formed at the drain electrode.

9. The method of claim 8, wherein, in step 2, the sequentially depositing of the gate insulating layer, the active layer, and the source-drain conductor layer is continuously performed.

10. The method of claim 8, wherein, in step 2, etching the portion of the source-drain conductor layer at the channel and the active layer at the channel region is continuously performed.
